(19) United States
(12) Patent Application Publication
(10) Pub. No.: US 2025/0338699 A1
(43) Pub. Date: Oct. 30, 2025

(54) DISPLAY DEVICE AND ELECTRONIC DEVICE

(71) Applicant: Samsung Display Co., LTD., Yongin-si (KR)

(72) Inventor: GICHANG LEE, Yongin-si (KR)

(73) Assignee: Samsung Display Co., LTD., Yongin-si (KR)

(21) Appl. No.: 19/022,258

(22) Filed: Jan. 15, 2025

(30) Foreign Application Priority Data
Apr. 25, 2024 (KR) 10-2024-0055466

(51) Int. Cl. H10H 29/85; H01L 25/16; H10H 29/49

(52) U.S. Cl. CPC H10H 29/8582; H01L 25/167; H10H 29/49

(57) ABSTRACT

A display device includes a substrate, a display panel driver disposed on the substrate, data lines disposed on the substrate, electrically connected to the display panel driver, and each extending in a first direction, and a heat dissipation pattern disposed on the substrate, overlapping at least a portion of the data lines in a plan view, and extended to the substrate through contact holes.

### CROSS-REFERENCE TO RELATED APPLICATION(S)

This application claims priority to and benefits of Korean Patent Application No. 10-2024-0055466 under 35 USC § 119, filed on Apr. 25, 2024 in the Korean Intellectual Property Office (KIPO), the entire contents of which are incorporated herein by reference.

### BACKGROUND

### 1. Technical Field

Embodiments relate to a display device.

### 2. Description of the Related Art

A display device includes a display area and a non-display area. In the display area of the display device, a driving element (e.g., a transistor) and a light emitting element (e.g., an organic light emitting diode) are disposed. The light emitting element receives a voltage or signal from the driving element and emits light, so that an image may be displayed. In the non-display area of the display device in which the light emitting element is not disposed, an image may not be displayed. In the non-display area of the display device, a driving integrated circuit, a pad, or the like may be disposed to provide a voltage or signal to the light emitting element.

### SUMMARY

Embodiments provide a display device with improved reliability.

Embodiments provide an electronic device including the display device.

A display device according to an embodiment of the disclosure may include a substrate, a display panel driver disposed on the substrate, data lines disposed on the substrate, electrically connected to the display panel driver, and each extending in a first direction, and a heat dissipation pattern disposed on the substrate, overlapping at least a portion of the data lines in a plan view, and extended to the substrate through contact holes.

In an embodiment, the data lines may each be disposed between contact holes adjacent to each other among the contact holes.

In an embodiment, the heat dissipation pattern may include a first heat dissipation pattern extended to the substrate through first contact holes, and at least one second heat dissipation pattern disposed on the first heat dissipation pattern and extended to the first heat dissipation pattern through second contact holes.

In an embodiment, the data lines may be disposed below the first heat dissipation pattern.

In an embodiment, the data lines may be disposed between the first heat dissipation pattern and the second heat dissipation pattern.

In an embodiment, the first contact holes and the second contact holes may overlap in the plan view.

In an embodiment, the data lines and the contact holes may be alternately disposed in a second direction intersecting the first direction.

In an embodiment, the heat dissipation pattern may include a line portion extending in the second direction, overlapping the data lines in the plan view, and extended to the substrate through the contact holes, and a pad portion extended to the line portion and spaced apart from the data lines in the plan view.

In an embodiment, the heat dissipation pattern may surround each of the data lines in a cross-sectional view.

In an embodiment, the display device may further include a heat dissipation film disposed on the heat dissipation pattern.

In an embodiment, the substrate may include a silicon wafer.

A display device according to an embodiment of the disclosure may include a substrate, a display panel driver disposed on the substrate, data lines disposed on the substrate, electrically connected to the display panel driver, and each extending in a first direction, and a heat dissipation pattern disposed on the substrate and surrounding each of the data lines in a cross-sectional view.

In an embodiment, the heat dissipation pattern may include a first heat dissipation pattern disposed on the substrate and extended to the substrate, and at least one second heat dissipation pattern disposed on the first heat dissipation pattern and extended to the first heat dissipation pattern.

In an embodiment, the data lines may be disposed below the first heat dissipation pattern.

In an embodiment, the data lines may be disposed between the first heat dissipation pattern and the second heat dissipation pattern.

In an embodiment, the heat dissipation pattern may be extended to the substrate through contact holes.

In an embodiment, the data lines may each be disposed between contact holes adjacent to each other among the contact holes.

In an embodiment, the data lines and the contact holes may be alternately disposed in a second direction intersecting the first direction.

In an embodiment, the heat dissipation pattern may include a line portion extending in the second direction, overlapping the data lines in a plan view, and extended to the substrate through the contact holes, and a pad portion connected to the line portion and spaced apart from the data lines in the plan view.

In an embodiment, the display device may further include a heat dissipation film disposed on the heat dissipation pattern.

An electronic device according to an embodiment of the disclosure includes a display device and a power supply that provides power to the display device. The display device includes a substrate, a display panel driver disposed on the substrate, data lines disposed on the substrate, electrically connected to the display panel driver, and each extending in a first direction, and a heat dissipation pattern disposed on the substrate, overlapping at least a portion of the data lines in a plan view, and extended to the substrate through contact holes.

In a display device according to embodiments of the disclosure, the display device may include a heat dissipation pattern disposed in a non-display area and overlapping data lines in a plan view. The heat dissipation pattern may be connected to a substrate through contact holes, and the data lines may be respectively disposed between the contact holes. Heat generated from a display panel driver and conducted through the substrate may be dissipated by the heat dissipation pattern connected through the contact holes, and heat generated from the display panel driver and conducted through the data lines may be dissipated by the heat dissipation pattern surrounding the data lines. Accordingly, damage caused by heat of pixels disposed in a display area may be minimized, and thus reliability of the display device may be improved. Since an additional space to dissipate heat generated from the display panel driver is not required between the display panel driver and the display area, dead space of the display device may be minimized.

### BRIEF DESCRIPTION OF THE DRAWINGS

FIG. 1 is a schematic plan view illustrating a display device according to an embodiment of the disclosure.

FIG. 2 is an enlarged schematic plan view of area A of FIG. 1.

FIG. 3 is a schematic cross-sectional view taken along line I-I′ of FIG. 2.

FIG. 4 is a schematic cross-sectional view taken along line II-II′ of FIG. 2.

FIG. 5 is a schematic cross-sectional view taken along line I-I′ of FIG. 2.

FIG. 6 is a schematic cross-sectional view taken along line II-II′ of FIG. 2.

FIG. 7 is a schematic cross-sectional view illustrating an example of a pixel included in the display device of FIG. 1.

FIG. 8 is a schematic block diagram illustrating an electronic device according to an embodiment of the disclosure.

FIG. 9 is a schematic view illustrating an example in which the electronic device of FIG. 8 is implemented as a smart phone.

### DETAILED DESCRIPTION OF THE EMBODIMENTS

Hereinafter, embodiments of the disclosure will be described in more detail with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art. The same reference numerals are used for the same components in the drawings, and redundant descriptions of the same components will be omitted.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or “to not overlap” another element, this may include that the elements are spaced apart from each other, offset from each other, or set aside from each other or any other suitable term as would be appreciated and understood by those of ordinary skill in the art.

In the specification and the claims, the phrase “at least one of” is intended to include the meaning of “at least one selected from the group of” for the purpose of its meaning and interpretation. For example, “at least one of A and B” may be understood to mean “A, B, or A and B.”

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be understood that the terms “connected to” or “coupled to” may include a physical or electrical connection or coupling. It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

The phrase “in a plan view” means viewing the object from the top, and the phrase “in a schematic cross-sectional view” means viewing a cross-section of which the object is vertically cut from the side.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

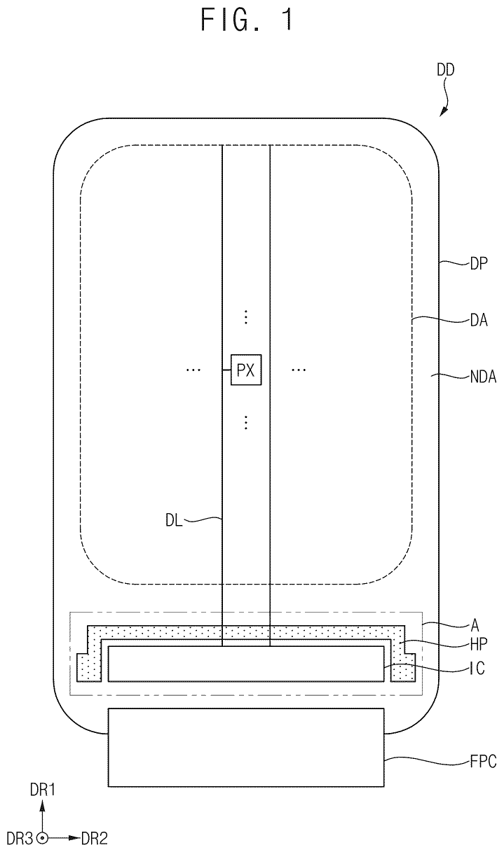

FIG. 1 is a schematic plan view illustrating a display device according to an embodiment of the disclosure.

Referring to FIG. 1, a display device DD may define a display area DA and a non-display area NDA. The display device DD may include a display panel DP, a display panel driver IC, and a printed circuit board FPC.

The display area DA may be an area that displays an image, and the non-display area NDA may be an area that does not display an image. A driver for displaying an image of the display area DA may be disposed in the non-display area NDA. The non-display area NDA may be disposed around the display area DA. For example, the non-display area NDA may surround the display area DA in a plan view.

The display panel DP may include pixels PX disposed in the display area DA. The pixels PX may be repeatedly disposed along or in a first direction DR1 and a second direction DR2 intersecting the first direction DR1. For example, the first direction DR1 may be perpendicular to the second direction DR2. Each of the pixels PX may emit light. As each of the pixels PX emits light, an image may be displayed in the display area DA. For example, in the display area DA, the image may be displayed in a third direction DR3 intersecting each of the first direction DR1 and the second direction DR2. For example, the third direction DR3 may be perpendicular to each of the first direction DR1 and the second direction DR2.

The display panel DP may further include data lines DL and a heat dissipation pattern HP. The data lines DL may extend from the non-display area NDA to the display area DA, and the heat dissipation pattern HP may be disposed in the non-display area NDA. For example, each of the data lines DL may extend in the first direction DR1, and the data lines DL may be spaced apart from each other in the second direction DR2. The data lines DL may be electrically connected to the pixels PX, respectively.

The display panel driver IC may be disposed in the non-display area NDA. The display panel driver IC may overlap the display panel DP in a plan view. The display panel driver IC may be connected to the data lines DL. That is, the display panel driver IC may be electrically connected to the display panel DP.

The display panel driver IC may include a data driver and a timing controller. For example, the display panel driver IC may be a timing controller embedded data driver (“TED”) in which the data driver and the timing controller are implemented as a single integrated circuit. As the display panel driver IC includes the data driver, the display panel driver IC may provide data signals to the pixels PX. The display panel driver IC may provide the data signals to the pixels PX through the data lines DL.

The printed circuit board FPC may be disposed in the non-display area NDA. The printed circuit board FPC may include driving circuits for driving the display device DD, a connector for supplying power, or the like. The printed circuit board FPC may partially overlap the display panel DP in a plan view. A part of the printed circuit board FPC may overlap the display panel DP in a plan view, and another part of the printed circuit board FPC may not overlap the display panel DP in a plan view. The printed circuit board FPC may be electrically connected to the display panel driver IC and the display panel DP.

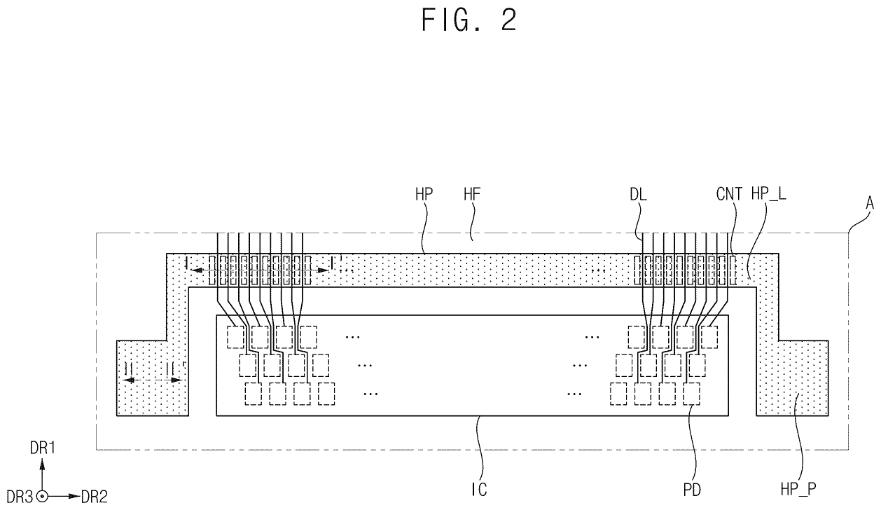

FIG. 2 is an enlarged schematic plan view of area A of FIG. 1. FIG. 2 may be an enlarged plan view of a part of the non-display area NDA of the display device DD.

Referring to FIGS. 1 and 2, the display device DD may include the display panel driver IC, the data lines DL, and the heat dissipation pattern HP.

The display panel driver IC may be disposed in the non-display area NDA. The data lines DL may extend from the non-display area NDA to the display area DA, and may be connected to the display panel driver IC in the non-display area NDA. The data lines DL may extend in the first direction DR1, respectively, and may be spaced apart from each other in the second direction DR2.

The display panel driver IC may include pads PD connected to the data lines DL, respectively. The pads PD may be spaced apart from each other along the first direction DR1 or the second direction DR2. The display panel driver IC may be connected to the data lines DL through the pads PD, and accordingly, may provide the data signals to the pixels PX.

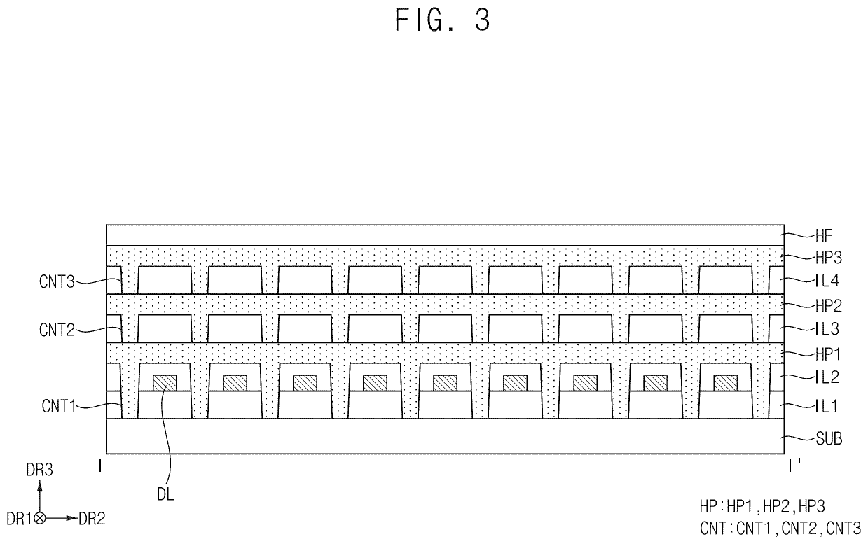

The heat dissipation pattern HP may be disposed in the non-display area NDA. The heat dissipation pattern HP may define contact holes CNT. The contact holes CNT may be spaced apart from each other along the second direction DR2. In an embodiment, the heat dissipation pattern HP may be connected to a component (e.g., a substrate SUB of FIG. 3) disposed below the heat dissipation pattern HP through the contact holes CNT.

In an embodiment, the data lines DL may be disposed between contact holes CNT adjacent to each other among the contact holes CNT. For example, in an area in which the heat dissipation pattern HP and the data lines DL overlap in a plan view, the contact holes CNT and the data lines DL may be alternately disposed along the second direction DR2.

The heat dissipation pattern HP may include a line portion HP_L and a pad portion HP_P. The line portion HP_L may extend in the second direction DR2, and may overlap the data lines DL in a plan view. The line portion HP_L may define the contact holes CNT. The pad portion HP_P may be connected to the line portion HP_L, and may be spaced apart from the data lines DL in a plan view. For example, the line portion HP_L may be a portion surrounding a part of the display panel driver IC, and the pad portion HP_P may be a portion surrounding another part of the display panel driver IC. The pad portion HP_P may be a portion having a relatively large area among the heat dissipation pattern HP.

The display device DD may further include a heat dissipation film HF. The heat dissipation film HF may be disposed on the display panel driver IC, the data lines DL, and the heat dissipation pattern HP. The heat dissipation film HF may cover the display panel driver IC, the data lines DL, and the heat dissipation pattern HP as a whole. The heat dissipation film HF may dissipate to the outside, heat that may be generated while the display device DD is driven. For example, the heat dissipation film HF may dissipate heat that may be generated from the display panel driver IC to the outside.

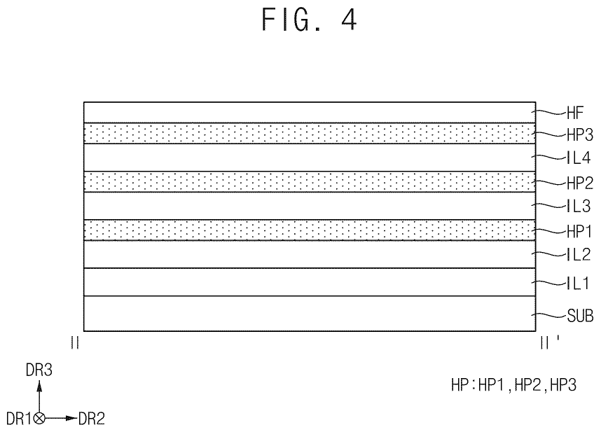

FIG. 3 is a schematic cross-sectional view taken along line I-I′ of FIG. 2. FIG. 4 is a schematic cross-sectional view taken along line II-II′ of FIG. 2.

For example, FIG. 3 may be a cross-sectional view of a part of an area in which the line portion HP_L of the heat dissipation pattern HP is disposed, and FIG. 4 may be a cross-sectional view of a part of an area in which the pad portion HP_P of the heat dissipation pattern HP is disposed.

Referring to FIGS. 1, 2, 3, and 4, the display device DD may include a substrate SUB, an insulating layer, the data lines DL, the heat dissipation pattern HP, and the heat dissipation film HF.

The insulating layer may include a first insulating layer IL1, a second insulating layer IL2, a third insulating layer IL3, and a fourth insulating layer IL4, and the heat dissipation pattern HP may include a first heat dissipation pattern HP1, a second heat dissipation pattern HP2, and a third heat dissipation pattern HP3.

The substrate SUB may include a transparent material or an opaque material. Examples of materials that may be used as the substrate SUB may include silicon, polyimide, quartz, glass, or the like. These may be used alone or in combination with each other. In an embodiment, the substrate SUB may be a silicon wafer substrate. The substrate SUB may include a silicon wafer.

The first insulating layer IL1 may be disposed on the substrate SUB, and the data lines DL may be disposed on the first insulating layer IL1. The data lines DL may be arranged along the second direction DR2.

The second insulating layer IL2 may be disposed on the first insulating layer IL1 and the data lines DL. The second insulating layer IL2 may cover the data lines DL.

The first heat dissipation pattern HP1 may be disposed on the second insulating layer IL2. The first heat dissipation pattern HP1 may be connected to the substrate SUB through first contact holes CNT1. The first contact holes CNT1 may be formed in an area in which the heat dissipation pattern HP and the data lines DL overlap in a plan view. Each of the first contact holes CNT1 may penetrate the first and second insulating layers IL1 and IL2 in a direction opposite to the third direction DR3. The first contact holes CNT1 may be arranged along the second direction DR2.

In an embodiment, the data lines DL may be respectively disposed between first contact holes CNT1 adjacent to each other among the first contact holes CNT1. That is, in an area in which the heat dissipation pattern HP and the data lines DL overlap in a plan view, the first contact holes CNT1 and the data lines DL may be alternately disposed along the second direction DR2. Accordingly, the first heat dissipation pattern HP1 may surround each of the data lines DL in a cross-sectional view. For example, the first heat dissipation pattern HP1 may surround an upper surface and a side surface of each of the data lines DL in a cross-sectional view.

The third insulating layer IL3 may be disposed on the first heat dissipation pattern HP1, and the second heat dissipation pattern HP2 may be disposed on the third insulating layer IL3.

The second heat dissipation pattern HP2 may be connected to the first heat dissipation pattern HP1 through second contact holes CNT2. The second contact holes CNT2 may be formed in an area in which the heat dissipation pattern HP and the data lines DL overlap in a plan view. Each of the second contact holes CNT2 may penetrate the third insulating layer IL3 in the direction opposite to the third direction DR3. The second contact holes CNT2 may be arranged along the second direction DR2. The second contact holes CNT2 may overlap the first contact holes CNT1 in a plan view, respectively.

The fourth insulating layer IL4 may be disposed on the second heat dissipation pattern HP2, and the third heat dissipation pattern HP3 may be disposed on the fourth insulating layer IL4.

The third heat dissipation pattern HP3 may be connected to the second heat dissipation pattern HP2 through third contact holes CNT3. The third contact holes CNT3 may be formed in an area in which the heat dissipation pattern HP and the data lines DL overlap in a plan view. Each of the third contact holes CNT3 may penetrate the fourth insulating layer IL4 in the direction opposite to the third direction DR3. The third contact holes CNT3 may be arranged along the second direction DR2. The third contact holes CNT3 may overlap the first and second contact holes CNT1 and CNT2 in a plan view, respectively.

The heat dissipation film HF may be disposed on the third heat dissipation pattern HP3. Although FIGS. 3 and 4 illustrate that no other component is disposed between the third heat dissipation pattern HP3 and the heat dissipation film HF, the disclosure is not limited thereto. For example, another component may be further disposed between the third heat dissipation pattern HP3 and the heat dissipation film HF.

Accordingly, the heat dissipation pattern HP may be disposed to contact the substrate SUB through the contact holes CNT and surround each of the data lines DL in a cross-sectional view, and the heat dissipation film HF may be adjacent to the heat dissipation pattern HP.

Heat may be generated while the display panel driver IC disposed in the non-display area NDA is driven, and the heat may be conducted to the display area DA through the substrate SUB and the data lines DL to damage the pixels PX. The heat dissipation pattern HP and the heat dissipation film HF may serve to dissipate the heat generated by the display panel driver IC.

Specifically, since the heat dissipation pattern HP contacts the substrate SUB through the contact holes CNT, heat conducted through the substrate SUB may be conducted to the heat dissipation pattern HP. Since the heat dissipation pattern HP surrounds the data lines DL, heat conducted through the data lines DL may be conducted to the heat dissipation pattern HP. The heat conducted to the heat dissipation pattern HP may be dissipated (e.g., discharged) to the outside through the heat dissipation film HF adjacent to the heat dissipation pattern HP.

Since the pad portion HP_P of the heat dissipation pattern HP contacts (e.g., is adjacent to) the heat dissipation film HF in a relatively large area, heat generated from the display panel driver IC may be effectively dissipated. Since the heat dissipation pattern HP includes a multilayer structure (e.g., the first, second, and third heat dissipation patterns HP1, HP2, and HP3), thermal conductivity of the heat dissipation pattern HP may be increased and resistance of the heat dissipation pattern HP may be decreased, so that the heat generated from the display panel driver IC may be more effectively dissipated.

Each of the first, second, third, and fourth insulating layers IL1, IL2, IL3, and IL4 may include an inorganic material or an organic material. For example, the insulating layer may include an inorganic material such as silicon oxide (SiOₓ), silicon nitride (SiNₓ), silicon oxynitride (SiOₓN_{y}), or the like, or an organic material such as phenol resin, acryl resin, polyimide resin, polyamide resin, siloxane resin, epoxy resin, or the like. These may be used alone or in combination with each other. Each of the first, second, third, and fourth insulating layers IL1, IL2, IL3, and IL4 may have a single layer structure or a multilayer structure.

Each of the first, second, and third heat dissipation patterns HP1, HP2, and HP3 may include a metal, an alloy, a conductive metal nitride, a conductive metal oxide, a transparent conductive material, or the like. These may be used alone or in combination with each other. In an embodiment, each of the first, second, and third heat dissipation patterns HP1, HP2, and HP3 may include a material having high thermal conductivity. For example, each of the first, second, and third heat dissipation patterns HP1, HP2, and HP3 may include aluminum (Al), copper (Cu), or the like. Each of the first, second, and third heat dissipation patterns HP1, HP2, and HP3 may have a single layer structure or a multilayer structure.

In an embodiment, the heat dissipation pattern HP and the data lines DL may include a same material. However, the disclosure is not limited thereto, and in another embodiment, the heat dissipation pattern HP and the data lines DL may include different materials.

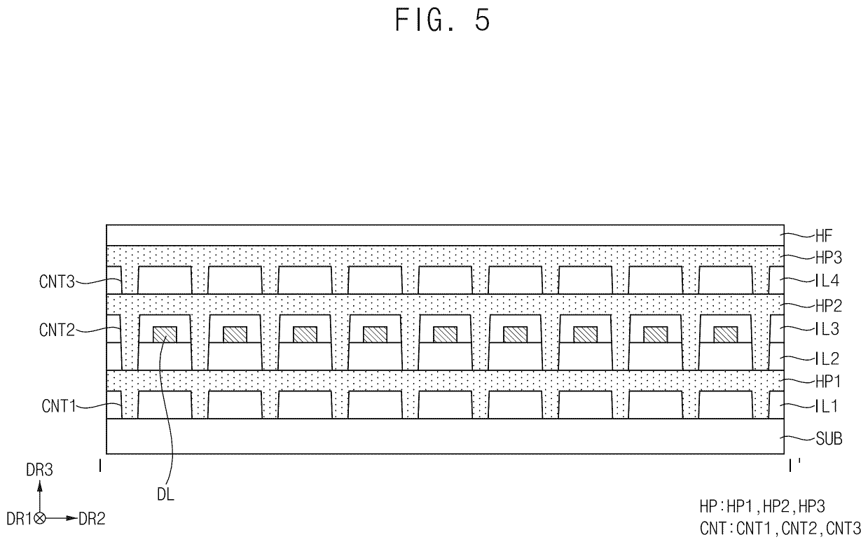

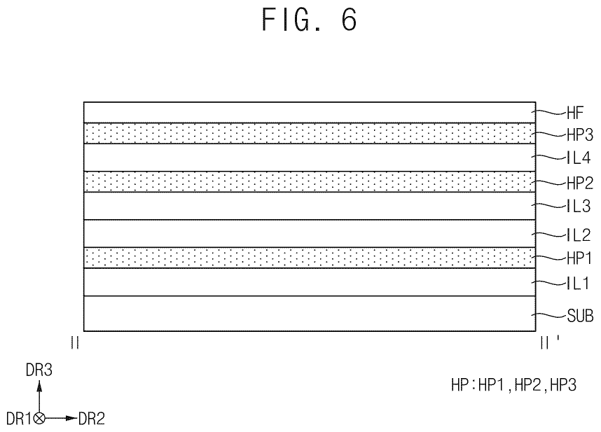

FIG. 5 is a schematic cross-sectional view taken along line I-I′ of FIG. 2. FIG. 6 is a schematic cross-sectional view taken along line II-II′ of FIG. 2.

For example, FIG. 5 may be a cross-sectional view of a part of an area in which the line portion HP_L of the heat dissipation pattern HP is disposed, and FIG. 6 may be a cross-sectional view of a part of an area in which the pad portion HP_P of the heat dissipation pattern HP is disposed.

An embodiment of the display device DD described with reference to FIGS. 5 and 6 may be substantially the same as or similar to an embodiment of the display device DD described with reference to FIGS. 3 and 4 at least except for a position of the data lines DL. Hereinafter, redundant descriptions will be omitted or simplified.

Referring to FIGS. 1, 2, 5, and 6, the display device DD may include a substrate SUB, an insulating layer, the data lines DL, the heat dissipation pattern HP, and the heat dissipation film HF.

The insulating layer may include a first insulating layer IL1, a second insulating layer IL2, a third insulating layer IL3, and a fourth insulating layer IL4, and the heat dissipation pattern HP may include a first heat dissipation pattern HP1, a second heat dissipation pattern HP2, and a third heat dissipation pattern HP3.

In an embodiment, the substrate SUB may be a silicon wafer substrate. The first insulating layer IL1 may be disposed on the substrate SUB, and the first heat dissipation pattern HP1 may be disposed on the first insulating layer IL1.

The first heat dissipation pattern HP1 may be connected to the substrate SUB through first contact holes CNT1. The first contact holes CNT1 may be formed in an area in which the heat dissipation pattern HP and the data lines DL overlap in a plan view. Each of the first contact holes CNT1 may penetrate the first insulating layer IL1 in a direction opposite to the third direction DR3. The first contact holes CNT1 may be arranged along the second direction DR2.

The second insulating layer IL2 may be disposed on the first heat dissipation pattern HP1, and the data lines DL may be disposed on the second insulating layer IL2. The data lines DL may be arranged along the second direction DR2.

The third insulating layer IL3 may be disposed on the second insulating layer IL2 and the data lines DL. The third insulating layer IL3 may cover the data lines DL.

The second heat dissipation pattern HP2 may be disposed on the third insulating layer IL3. The second heat dissipation pattern HP2 may be connected to the first heat dissipation pattern HP1 through second contact holes CNT2. The second contact holes CNT2 may be formed in an area in which the heat dissipation pattern HP and the data lines DL overlap in a plan view. Each of the second contact holes CNT2 may penetrate the second and third insulating layers IL2 and IL3 in the direction opposite to the third direction DR3. The second contact holes CNT2 may be arranged along the second direction DR2. The second contact holes CNT2 may overlap the first contact holes CNT1 in a plan view, respectively.

In an embodiment, the data lines DL may be respectively disposed between second contact holes CNT2 adjacent to each other among the second contact holes CNT2. For example, in an area in which the heat dissipation pattern HP and the data lines DL overlap in a plan view, the second contact holes CNT2 and the data lines DL may be alternately disposed along the second direction DR2. Accordingly, the first and second heat dissipation patterns HP1 and HP2 may surround each of the data lines DL in a cross-sectional view. For example, the first heat dissipation pattern HP1 may surround a lower surface of each of the data lines DL in a cross-sectional view, and the second heat dissipation pattern HP2 may surround an upper surface and a side surface of each of the data lines DL in a cross-sectional view.

The fourth insulating layer IL4 may be disposed on the second heat dissipation pattern HP2, and the third heat dissipation pattern HP3 may be disposed on the fourth insulating layer IL4.

The third heat dissipation pattern HP3 may be connected to the second heat dissipation pattern HP2 through third contact holes CNT3. The third contact holes CNT3 may be formed in an area in which the heat dissipation pattern HP and the data lines DL overlap in a plan view. Each of the third contact holes CNT3 may penetrate the fourth insulating layer IL4 in the direction opposite to the third direction DR3. The third contact holes CNT3 may be arranged along the second direction DR2. The third contact holes CNT3 may overlap the first and second contact holes CNT1 and CNT2 in a plan view, respectively.

The heat dissipation film HF may be disposed on the third heat dissipation pattern HP3.

Accordingly, the heat dissipation pattern HP may be disposed to contact the substrate SUB through the contact holes CNT and surround each of the data lines DL in a cross-sectional view, and the heat dissipation film HF may be adjacent to the heat dissipation pattern HP.

The heat dissipation pattern HP and the heat dissipation film HF may serve to dissipate heat generated by the display panel driver IC. Specifically, since the heat dissipation pattern HP contacts the substrate SUB through the contact holes CNT, heat conducted from the display panel driver IC through the substrate SUB may be conducted to the heat dissipation pattern HP. Since the heat dissipation pattern HP surrounds the data lines DL, heat conducted from the display panel driver IC through the data lines DL may be conducted to the heat dissipation pattern HP. The heat conducted to the heat dissipation pattern HP may be dissipated (e.g., discharged) to outside through the heat dissipation film HF adjacent to the heat dissipation pattern HP.

Since the pad portion HP_P of the heat dissipation pattern HP contacts (e.g., is adjacent to) the heat dissipation film HF in a relatively large area, heat generated from the display panel driver IC may be effectively dissipated. Since the heat dissipation pattern HP includes a multilayer structure (e.g., the first, second, and third heat dissipation patterns HP1, HP2, and HP3), thermal conductivity of the heat dissipation pattern HP may be increased and resistance of the heat dissipation pattern HP may be decreased, so that the heat generated from the display panel driver IC may be more effectively dissipated.

Each of the first, second, third, and fourth insulating layers IL1, IL2, IL3, and IL4 may include an inorganic material or an organic material, and may have a single layer structure or a multilayer structure. Each of the first, second, and third heat dissipation patterns HP1, HP2, and HP3 may include a material having high thermal conductivity, and may have a single layer structure or a multilayer structure.

Although FIGS. 3, 4, 5, and 6 illustrate that the display device DD includes four insulating layers (e.g., the first, second, third, and fourth insulating layers IL1, IL2, IL3, and IL4) and three heat dissipation patterns (e.g., the first, second, and third heat dissipation patterns HP1, HP2, and HP3) in the non-display area NDA, the disclosure is not limited thereto. For example, the display device DD may include one or more insulating layers and one or more heat dissipation patterns in the non-display area NDA.

Although FIG. 3 illustrates that the data lines DL are disposed below the first heat dissipation pattern HP1 and FIG. 5 illustrates that the data lines DL are disposed between the first heat dissipation pattern HP1 and the second heat dissipation pattern HP2, the disclosure is not limited thereto. For example, the data lines DL may be disposed between the second heat dissipation pattern HP2 and the third heat dissipation pattern HP3. For example, the data lines DL may be variously disposed below the uppermost layer of the heat dissipation pattern HP.

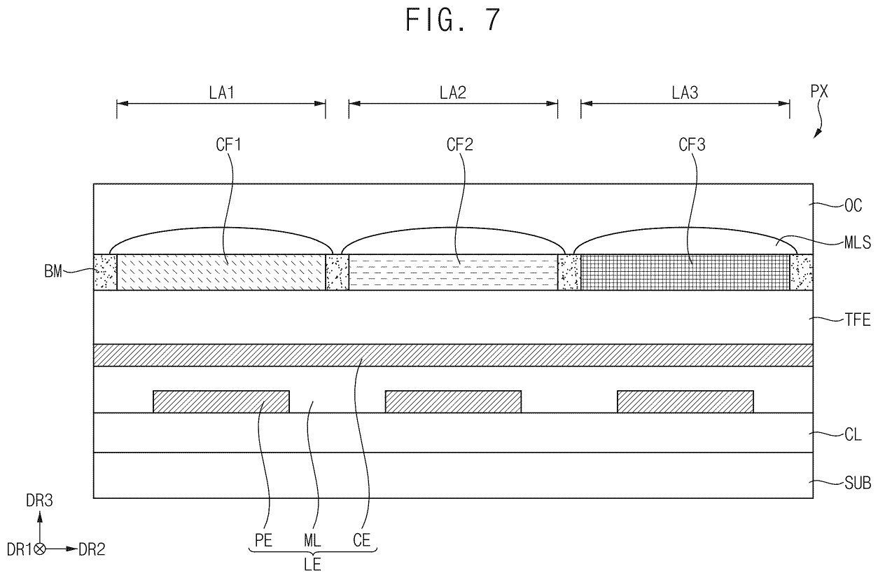

FIG. 7 is a schematic cross-sectional view illustrating an example of a pixel included in the display device of FIG. 1. FIG. 7 may be a cross-sectional view illustrating a part of the display area DA of the display device DD.

Referring to FIGS. 1 and 7, the pixel PX included in the display device DD may define a first light emitting area LA1, a second light emitting area LA2, and a third light emitting area LA3. Each of the first, second, and third light emitting areas LA1, LA2, and LA3 may mean an area in which light emitted from a light emitting element LE included in the display device DD is emitted to the outside of the display device DD. The first, second, and third light emitting areas LA1, LA2, and LA3 may emit light of different wavelength bands. For example, the first light emitting area LA1 may emit light of a red wavelength band, the second light emitting area LA2 may emit light of a green wavelength band, and the third light emitting area LA3 may emit light of a blue wavelength band, but the disclosure is not limited thereto.

The display device DD may include the substrate SUB, a circuit layer CL, the light emitting element LE, an encapsulation layer TFE, a partition wall or bank BM, a first color filter CF1, a second color filter CF2, a third color filter CF3, microlens MLS, and a planarization layer OC in the display area DA. The light emitting element LE may include a pixel electrode PE, an intermediate layer ML, and a common electrode CE.

The substrate SUB may include a transparent material or an opaque material. Examples of materials that may be used as the substrate SUB may include silicon, polyimide, quartz, glass, or the like. These may be used alone or in combination with each other. In an embodiment, the substrate SUB may be a silicon wafer substrate.

The circuit layer CL may be disposed on the substrate SUB. The circuit layer may include various driving elements, lines, or the like for driving the light emitting element LE. For example, the circuit layer CL may include a transistor, a capacitor, a gate line, the data line DL, or the like.

The pixel electrode PE may be disposed on the circuit layer CL. The pixel electrode PE may be disposed in each of the first, second, and third light emitting areas LA1, LA2, and LA3 on the circuit layer CL. The pixel electrode PE may be electrically connected to the transistor included in the circuit layer CL. The pixel electrode PE may include a metal, an alloy, a conductive metal nitride, a conductive metal oxide, a transparent conductive material, or the like. These may be used alone or in combination with each other.

The intermediate layer ML may be disposed on the circuit layer CL and the pixel electrode PE. In an embodiment, the intermediate layer ML may include a material that emits light. The intermediate layer ML may include at least one light emitting layer and at least one auxiliary layer disposed below or on the light emitting layer. The light emitting layer may include a material that emits light of a preset color, and the auxiliary layer may include at least one of a hole injection layer, a hole transport layer, an electron injection layer, and an electron transport layer.

The common electrode CE may be disposed on the intermediate layer ML. For example, the common electrode CE may continuously extend over the first, second, and third light emitting areas LA1, LA2, and LA3. The common electrode CE may include a metal, an alloy, a conductive metal nitride, a conductive metal oxide, a transparent conductive material, or the like. These may be used alone or in combination with each other.

Accordingly, the light emitting element LE including the pixel electrode PE, the intermediate layer ML, and the common electrode CE may be disposed in the first, second, and third light emitting areas LA1, LA2, and LA3 on the substrate SUB, respectively. Since the intermediate layer ML emits light based on a voltage difference between the pixel electrode PE and the common electrode CE, light may be emitted from each of the first, second, and third light emitting areas LA1, LA2, and LA3.

The encapsulation layer TFE may be disposed on the common electrode CE. The encapsulation layer TFE may include at least one inorganic encapsulation layer and at least one organic encapsulation layer. For example, the encapsulation layer TFE may include a first inorganic layer, an organic layer, and a second inorganic layer stacked on each other, but the disclosure is not limited thereto. The encapsulation layer TFE may prevent foreign substances from penetrating into the light emitting element LE.

The bank BM may be disposed on the encapsulation layer TFE. The bank BM may define the first, second, and third light emitting areas LA1, LA2, and LA3. For example, the bank BM may define openings that define the first, second, and third light emitting areas LA1, LA2, and LA3. The openings may overlap the first, second, and third light emitting areas LA1, LA2, and LA3 in a plan view, respectively.

In an embodiment, the bank BM may include a light blocking material. Examples of the light blocking material may include an organic material or an inorganic material including a black pigment, a black dye, or the like. However, the disclosure is not limited thereto, and the bank BM may include a reflective material such as a metal material. Accordingly, the bank BM may prevent color mixing between the first, second, and third light emitting areas LA1, LA2, and LA3.

The first, second, and third color filters CF1, CF2, and CF3 may be disposed on the encapsulation layer TFE, and may be disposed in the openings defined by the bank BM, respectively. The first color filter CF1 may be disposed in an opening of the first light emitting area LA1, the second color filter CF2 may be disposed in an opening of the second light emitting area LA2, and the third color filter CF3 may be disposed in an opening of the third light emitting area LA3.

Each of the first, second, and third color filters CF1, CF2, and CF3 may selectively transmit light of a specific wavelength band, and may absorb light of a wavelength band different from the specific wavelength band. The first, second, and third color filters CF1, CF2, and CF3 may selectively transmit light of different wavelength bands. Accordingly, light of a wavelength band that the first, second, and third color filters CF1, CF2, and CF3 selectively transmit may be emitted from the first, second, and third light emitting areas LA1, LA2, and LA3, respectively. For example, the first color filter CF1 may selectively transmit light of a red wavelength band, the second color filter CF2 may selectively transmit light of a green wavelength band, and the third color filter CF3 may selectively transmit light of a blue wavelength band. Accordingly, light of a red wavelength band may be emitted from the first light emitting area LA1, light of a green wavelength band may be emitted from the second light emitting area LA2, and light of a blue wavelength band may be emitted from the third light emitting area LA3, but the disclosure is not limited thereto.

The microlens MLS may be disposed on the first, second, and third color filters CF1, CF2, and CF3. The microlens MLS may have a predetermined or selected refractive index, and may improve light extraction efficiency.

The planarization layer OC may be disposed on the microlens MLS. The planarization layer OC may include an organic material or an inorganic material. The planarization layer OC may compensate for a step difference caused by components disposed below the planarization layer OC (e.g., the first, second, and third color filters CF1, CF2, and CF3, the microlens MLS, or the like).

The display device DD according to an embodiment of the disclosure may include the heat dissipation pattern HP disposed in the non-display area NDA and overlapping the data lines DL in a plan view. The heat dissipation pattern HP may be connected to the substrate SUB through the contact holes CNT, and the data lines DL may be respectively disposed between the contact holes CNT. Heat generated from the display panel driver IC and conducted through the substrate SUB may be dissipated by the heat dissipation pattern HP connected through the contact holes CNT, and heat generated from the display panel driver IC and conducted through the data lines DL may be dissipated by the heat dissipation pattern HP surrounding the data lines DL. Accordingly, damage caused by heat of the pixels PX disposed in the display area DA may be minimized, and thus reliability of the display device DD may be improved. Since no additional space is required between the display panel driver IC disposed in the non-display area NDA and the display area DA to dissipate heat generated from the display panel driver IC, dead space of the display device DD may be minimized.

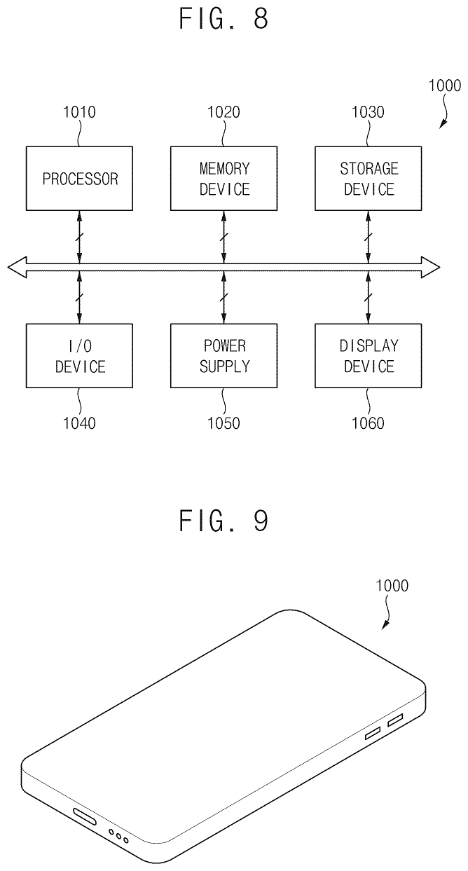

FIG. 8 is a schematic block diagram illustrating an electronic device according to an embodiment of the disclosure. FIG. 9 is a schematic view illustrating an example in which the electronic device of FIG. 8 is implemented as a smart phone.

Referring to FIGS. 8 and 9, the electronic device 1000 may include a processor 1010, a memory device 1020, a storage device 1030, an input/output (I/O) device 1040, a power supply 1050, and a display device 1060. The display device 1060 may be the display device DD of FIG. 1. In addition, the electronic device 1000 may further include a plurality of ports for communicating with a video card, a sound card, a memory card, a universal serial bus (USB) device, other systems, or the like.

In an embodiment, as illustrated in FIG. 9, the electronic device 1000 may be implemented as the smart phone. However, the electronic device 1000 is not limited thereto. For example, the electronic device 1000 may be implemented as a cellular phone, a video phone, a smart pad, a smart watch, a tablet PC, a car navigation system, a computer monitor, a laptop, a head mounted display (HMD) device, or the like.

The processor 1010 may perform various computing functions. The processor 1010 may be a microprocessor, a central processing unit (CPU), an application processor (AP), or the like. The processor 1010 may be coupled to other components through an address bus, a control bus, a data bus, or the like. In an embodiment, the processor 1010 may be coupled to an extended bus such as a peripheral component interconnection (PCI) bus.

The memory device 1020 may store data for operations of the electronic device 1000. For example, the memory device 1020 may include at least one non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, or the like and/or at least one volatile memory device such as a dynamic random access memory (DRAM) device, a static random access memory (SRAM) device, a mobile DRAM device, or the like.

The storage device 1030 may include a solid-state drive (SSD) device, a hard disk drive (HDD) device, a CD-ROM device, or the like. The I/O device 1040 may include an input device such as a keyboard, a keypad, a mouse device, a touch-pad, a touch-screen, or the like, and an output device such as a printer, a speaker, or the like. In an embodiment, the I/O device 1040 may include the display device 1060.

The I/O device 1040 may include an input device such as a keyboard, a keypad, a mouse device, a touch-pad, a touch-screen, and the like, and an output device such as a printer, a speaker, and the like. In an embodiment, the I/O device 1040 may include the display device 1060.

The power supply 1050 may provide power for operations of the electronic device 1000. The display device 1060 may be connected to other components through buses or other communication links.

The disclosure can be applied to various display devices and electronic devices. For example, the disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the disclosure. Accordingly, all such modifications to the embodiments, and other embodiments, are intended to be included within the scope of the disclosure.

What is claimed is:

1. A display device, comprising:
a substrate;
a display panel driver disposed on the substrate;
data lines disposed on the substrate, electrically connected to the display panel driver, and each extending in a first direction; and
a heat dissipation pattern disposed on the substrate, overlapping at least a portion of the data lines in a plan view, and extended to the substrate through contact holes.

2. The display device of claim 1, wherein the data lines are each disposed between contact holes adjacent to each other among the contact holes.

3. The display device of claim 2, wherein the heat dissipation pattern includes:
a first heat dissipation pattern extended to the substrate through first contact holes; and
at least one second heat dissipation pattern disposed on the first heat dissipation pattern and extended to the first heat dissipation pattern through second contact holes.

4. The display device of claim 3, wherein the data lines are disposed below the first heat dissipation pattern.

5. The display device of claim 3, wherein the data lines are disposed between the first heat dissipation pattern and the second heat dissipation pattern.

6. The display device of claim 3, wherein the first contact holes and the second contact holes overlap in the plan view.

7. The display device of claim 2, wherein the data lines and the contact holes are alternately disposed in a second direction intersecting the first direction.

8. The display device of claim 7, wherein the heat dissipation pattern includes:
a line portion extending in the second direction, overlapping the data lines in the plan view, and extended to the substrate through the contact holes; and
a pad portion extended to the line portion and spaced apart from the data lines in the plan view.

9. The display device of claim 1, wherein the heat dissipation pattern surrounds each of the data lines in a cross-sectional view.

10. The display device of claim 1, further comprising:
a heat dissipation film disposed on the heat dissipation pattern.

11. The display device of claim 1, wherein the substrate includes a silicon wafer.

12. A display device, comprising:
a substrate;
a display panel driver disposed on the substrate;
data lines disposed on the substrate, electrically connected to the display panel driver, and each extending in a first direction; and
a heat dissipation pattern disposed on the substrate and surrounding each of the data lines in a cross-sectional view.

13. The display device of claim 12, wherein the heat dissipation pattern includes:
a first heat dissipation pattern disposed on the substrate and extended to the substrate; and
at least one second heat dissipation pattern disposed on the first heat dissipation pattern and extended to the first heat dissipation pattern.

14. The display device of claim 13, wherein the data lines are disposed below the first heat dissipation pattern.

15. The display device of claim 13, wherein the data lines are disposed between the first heat dissipation pattern and the second heat dissipation pattern.

16. The display device of claim 12, wherein the heat dissipation pattern is extended to the substrate through contact holes.

17. The display device of claim 16, wherein the data lines are each disposed between contact holes adjacent to each other among the contact holes.

18. The display device of claim 16, wherein the data lines and the contact holes are alternately disposed in a second direction intersecting the first direction.

19. The display device of claim 18, wherein the heat dissipation pattern includes:
a line portion extending in the second direction, overlapping the data lines in a plan view, and extended to the substrate through the contact holes; and
a pad portion connected to the line portion and spaced apart from the data lines in the plan view.

20. The display device of claim 12, further comprising:
a heat dissipation film disposed on the heat dissipation pattern.

21. An electronic device, comprising:
a display device; and
a power supply that provides power to the display device,
wherein the display device includes:
a substrate;
a display panel driver disposed on the substrate;
data lines disposed on the substrate, electrically connected to the display panel driver, and each extending in a first direction; and
a heat dissipation pattern disposed on the substrate, overlapping at least a portion of the data lines in a plan view, and extended to the substrate through contact holes.
